(19) United States
(12) Patent Application Publication
(10) Pub. No.: US 2025/0067808 A1
(43) Pub. Date: Feb. 27, 2025

(54) BATTERY SIMULATOR WITH A REDUCED NEED FOR ELECTRICAL COMPONENTS

(71) Applicant: dSPACE GmbH, Paderborn (DE)

(72) Inventors: Paul GRUBER, Paderborn (DE); Lars HANKELN, Paderborn (DE)

(73) Assignee: dSPACE GmbH, Paderborn (DE)

(21) Appl. No.: 18/771,670

(22) Filed: Jul. 12, 2024

(30) Foreign Application Priority Data
Aug. 22, 2023 (DE) 102023122410.7
Aug. 22, 2023 (EP) 23192609.8

(51) Int. Cl. G01R 31/3835; G01R 19/165; G01R 31/396

(52) U.S. Cl. CPC G01R 31/3835; G01R 19/16542; G01R 31/396

(57) ABSTRACT

A battery simulator comprising a first electrical circuit for providing a first cell voltage for simulating the electrical voltage of a first battery cell and a second electrical circuit for providing a second cell voltage for simulating the electrical voltage of a second battery cell. The first cell voltage is connected to a local circuit ground and the second cell voltage is connected to the same local circuit ground and connected in series to the first cell voltage in such a way that the local circuit ground forms a pole of the first cell voltage and the second cell voltage. A control electronics is set up to regulate the first cell voltage and the second cell voltage. A saving in components results from the control of two cell voltages by a single control electronics.

This nonprovisional application claims priority to European Patent Application No. 23192609.8, which was filed in Europe on Aug. 22, 2023, and to German Patent Application Nr. 102023122410.7, which was filed in Germany on Aug. 22, 2023, and which are both herein incorporated by reference.

### BACKGROUND OF THE INVENTION

### Field of the Invention

A battery simulator is a development system used in the conventional art to test the performance of a technical system intended to interact with a battery. The technical system can be, for example, a battery management system that controls the charging and discharging process of the cells of a battery, a battery-powered electric motor of an e-vehicle, a charging station, etc.

### Description of the Background Art

A battery comprises a large number of battery cells connected in series. Each battery cell is a galvanic cell that generates an individual cell voltage, so that the sum of all cell voltages results in the output voltage of the battery. Accordingly, a battery simulator known in the prior art provides a number of series-connected simulated, individually controllable cell voltages and additionally comprises a computer model that simulates the electrical behavior of a galvanic cell for each simulated cell voltage in order to calculate a target specification for the respective cell voltage.

The illustration in FIG. 1 shows in a simplified form a structure of a single simulated battery cell in a battery simulator according to the state of the art from the applicant's product portfolio. A DC-to-DC converter provides a supply voltage for operating the electrical components; a voltage regulator applies the simulated cell voltage to a designated subsection of the underlying electrical circuit and regulates it to a target value specified by the control electronics. The control electronics comprises, among others, measurement technology, a digital isolator, a microcontroller, and an auxiliary power supply.

A typical battery simulator is designed to simulate a large number of battery cells, as a result of which all individual components of the electrical circuit shown in FIG. 1 are also installed in corresponding numbers. Overall, this results in a high need for electrical components, which leads to a high price and a large space requirement for the battery simulator.

### SUMMARY OF THE INVENTION

It is therefore an object of the invention to reduce the need for electrical components for the construction of a battery simulator.

To achieve the object, a battery simulator is proposed in an example, which comprises a first electrical circuit. A first cell voltage drops across a first subsection of the electrical circuit for simulating the electrical voltage of a first battery cell. The electrical circuit further comprises control electronics for regulating the first cell voltage.

The first cell voltage is connected to a local circuit ground. A second cell voltage drops across a second subsection of the first electrical circuit to simulate the electrical voltage of a second battery cell. The second cell voltage is also regulated by the control electronics and is connected to the same local circuit ground as the first cell voltage. The second cell voltage is connected in series to the first cell voltage in such a way that the local circuit ground forms a pole of the first cell voltage and the second cell voltage.

The local circuit ground represents a well-defined common zero potential for both simulated cell voltages, the first cell voltage and the second cell voltage. A local circuit ground is to be understood as a ground according to the technical term known from electrical engineering, but which does not represent a global ground of the battery simulator, but is implemented locally within the first electrical circuit for the purpose of serving as a common zero potential, in particular exclusively, for the first cell voltage and for the second cell voltage.

An electrical circuit known in the prior art for simulating a battery cell, as described above and shown in FIG. 1, can simulate a single battery cell. In contrast, the first electrical circuit of the invention can simulate two battery cells and requires only a slightly higher additional expenditure for electrical components to apply the second cell voltage for the simulation of the second battery cell. The two cell voltages are shared by the electrical components of the control electronics and the voltage source for the supply voltage. Overall, accordingly, a substantially more efficient use of electrical components results for a battery emulator of the invention. In a battery emulator that simulates a large number of battery cells using multiple electrical circuits of the invention, the need for control electronics and local power supplies is halved compared to the state of the art.

The first electrical circuit advantageously comprises its own local voltage source, in particular a DC-to-DC converter, which is arranged to apply a supply voltage to the first electrical circuit for operating the electrical components of the first electrical circuit. Furthermore advantageously, the first electrical circuit comprises a first voltage regulator, which is supplied by the supply voltage and which is arranged and designed to apply the first cell voltage to the first subsection and to regulate it to a first setpoint value, and a second voltage regulator, which is arranged and designed to apply the second cell voltage to the second subsection and to regulate it to a second setpoint value.

Because both the first cell voltage and the second cell voltage are applied to the local circuit ground, it is reasonable to reverse one of the two cell voltages for reasons of symmetry. For example, therefore, if a first cell voltage defined as positive is directed towards the local circuit ground, then a second cell voltage defined as positive should be directed away from the local circuit ground. For this purpose, the first electrical circuit advantageously comprises an inverse converter which is supplied by the supply voltage and which is connected in parallel to the first voltage regulator, wherein the second voltage regulator is supplied by the output voltage of the inverse converter. The control electronics are set up to specify the first setpoint value to the first voltage regulator in such a way that the first setpoint value is the same as a target specification for the electrical voltage of the first battery cell, and to specify the second setpoint value to the second voltage regulator in such a way that the second setpoint value is the same as the negative value of a target specification for the electrical voltage of the second battery cell. Both target specifications can be defined, for example, by the aforementioned computer model for simulating the electrical behavior of a number of galvanic cells.

In order to be able to simulate more than just two battery cells, the battery simulator preferably comprises, in addition to the first electrical circuit, at least one second electrical circuit which is designed identical to the first electrical circuit and provides a third cell voltage in the same way as described above in order to simulate the electrical voltage of a third battery cell, and provides a fourth cell voltage in order to simulate the electrical voltage of a fourth battery cell. The second electrical circuit is electrically connected to the first electrical circuit in such a way that the first cell voltage, the second cell voltage, the third cell voltage, and the fourth cell voltage are connected in series to jointly simulate four battery cells connected in series. In the same way, the battery simulator can comprise any number of electrical circuits, all of which are designed identical to the first electrical circuit and are electrically connected to each other in such a way that all cell voltages simulated by the number of electrical circuits are connected in series in order to simulate a plurality of series-connected battery cells of a battery.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows as a simplified block diagram an electrical circuit known from the prior art for simulating a single battery cell in a battery simulator;

FIG. 2 shows as a simplified block diagram an electrical circuit of the invention for simulating two battery cells in a battery simulator; and

FIG. 3 is a detailed circuit diagram of the electrical circuit shown in FIG. 2.

### DETAILED DESCRIPTION

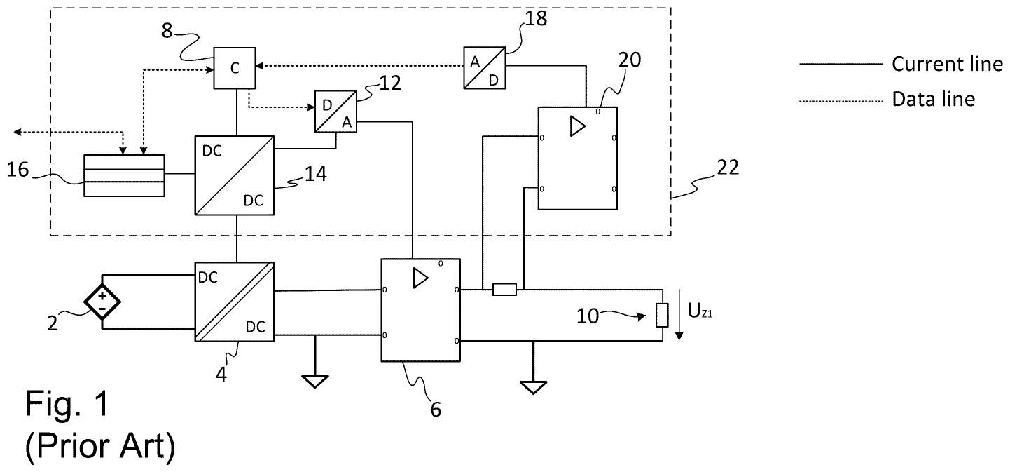

The illustration in FIG. 1 shows in the form of a block diagram an electrical circuit, known from the prior art, for simulating a first battery cell in a battery simulator. A DC-to-DC converter, supplied by a global power supply 2 of the battery simulator, as a voltage source 4 provides a supply voltage for a first voltage regulator 6. First voltage regulator 6 is arranged and designed to apply a first cell voltage U_{Z1} to a first subsection 10 of the electrical circuit. A microcontroller 8 specifies a first setpoint value to first voltage regulator 6 for the first cell voltage U_{Z1} with the aid of a digital-to-analog converter 12, and first voltage regulator 6 is designed to regulate the first cell voltage U_{Z1} to the first setpoint value. The microcontroller communicates via a digital isolator 16 with a computer model, implemented outside the electrical circuit, for simulating the electrical behavior of a number of galvanic cells of a battery, receives a target specification for the first cell voltage U_{Z1} from the computer model, and forwards the target specification as a setpoint value to first voltage regulator 6.

A differential amplifier 20 is arranged to measure the current strength of the current flowing through first subsection 10 and to forward the measured current strength to microcontroller 8 with the aid of an analog-to-digital converter 18. Microcontroller 8 forwards the actual current value to the battery simulator via digital isolator 16.

Accordingly, the electrical circuit comprises a plurality of electrical components which together form control electronics 22 for regulating the first cell voltage U_{Z1} and for measuring the current strength induced by the first cell voltage U_{Z1}. The control electronics comprises, among others, digital isolator 16, microcontroller 8, digital-to-analog converter 12, analog-to-digital converter 18, differential amplifier 20, and an auxiliary voltage supply 14 for providing an operating voltage for the electrical components of control electronics 22.

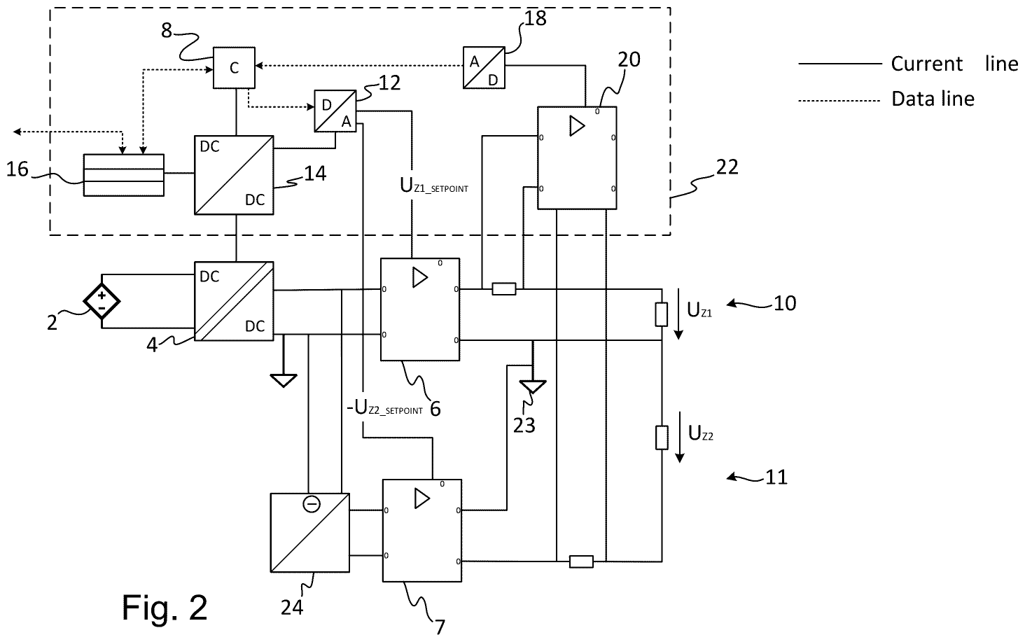

The illustration in FIG. 2 shows an electrical circuit for simulating the first cell voltage U_{Z1} and a second cell voltage U_{Z2} according to an exemplary embodiment of the invention. Only the differences from the electrical circuit shown in FIG. 1 will be explained hereinbelow.

An inverse converter 24 supplied by voltage supply 4 is connected in parallel to first voltage regulator 6, inverts the electrical voltage provided by voltage supply 4, and supplies a second voltage regulator 7 with the inverted voltage. Second voltage regulator 7 is arranged and designed to apply a second cell voltage U_{Z2} to a second subsection 11 of the electrical circuit. The microcontroller receives a second target specification for the second cell voltage U_{Z2} from the computer model in the same way as described above and passes a second setpoint value for the second cell voltage U_{Z2} to the second voltage regulator based on the target specification, wherein control electronics 22, however, is set up to invert the second setpoint value with respect to the target specification from the computer model. The second voltage regulator therefore receives as the second setpoint value the negative value of the second cell voltage U_{Z2}, which the computer model specifies as the second target specification.

Both the first cell voltage U_{Z1} and the second cell voltage U_{Z2} are connected to a common local circuit ground 23, which thus forms a well-defined common zero potential for the first cell voltage U_{Z1} and the second cell voltage U_{Z2}. By inverting the voltage applied to second voltage regulator 7 by inverse converter 24 and inverting the second setpoint value, it is achieved that a second cell voltage U_{Z2}, defined as positive, is directed away from the local circuit ground 23, whereas a first cell voltage U_{Z1}, defined as positive, is directed into local circuit ground 23.

Differential amplifier 20 is arranged and configured to additionally measure the current strength of the current flowing through second subsection 11 and to forward the measured current strength to microcontroller 8 in an analogous manner as previously described for forwarding to the battery simulator.

It is easy to see from the illustration that only a small additional expenditure for electrical components is required to provide the second cell voltage U_{Z2}. The additional expenditure is essentially limited to inverse converter 24, second voltage regulator 7, and a further measuring resistor. In a battery simulator, multiple electrical circuits, such as, for example, the one shown in FIG. 2, can be interconnected in such a way that all cell voltages simulated by the multiple electrical circuits are connected in series, so that overall a long series connection of independently controllable simulated cell voltages results. In a conventional state-of-the-art battery simulator, each individual cell voltage would be assigned its own control electronics 22 and its own voltage source 4. In a battery simulator of the invention, in each case two cell voltages share control electronics 22 and a voltage source 4. In a battery simulator, which is designed for simulating a large number of battery cells, this results in a significant saving of electrical components.

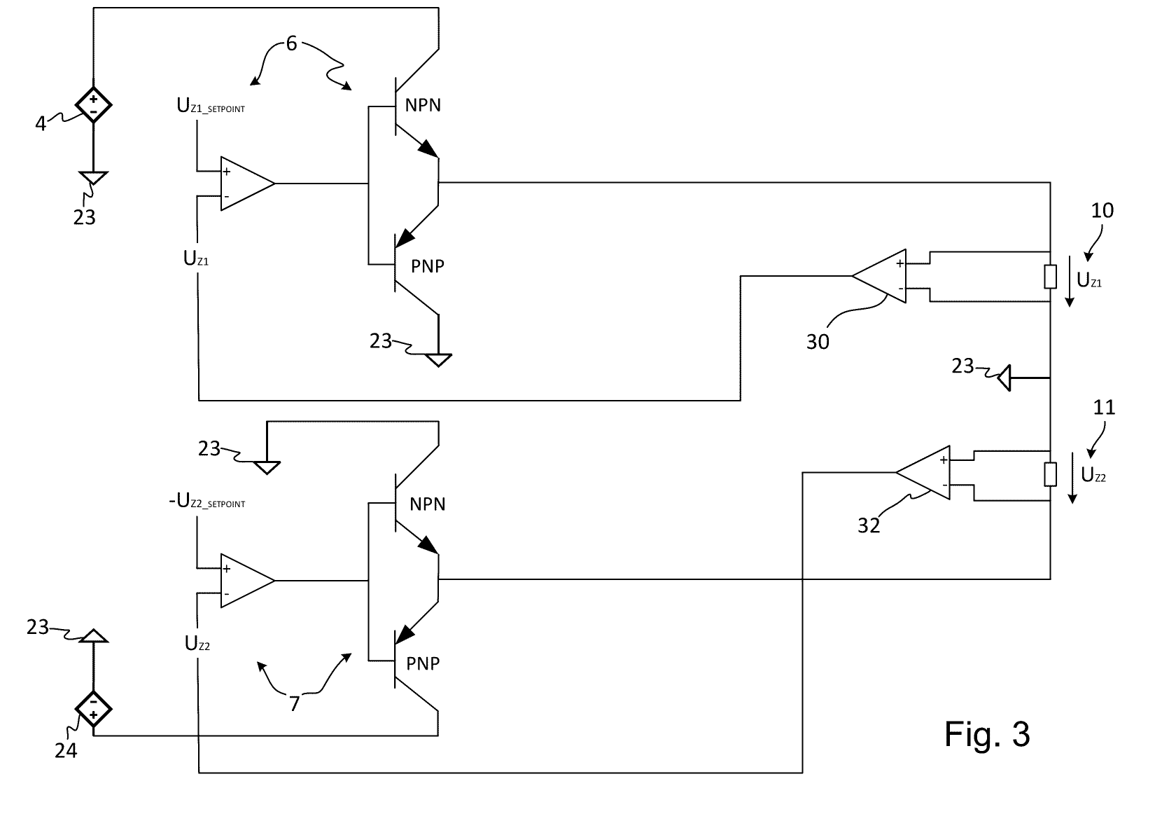

The illustration in FIG. 3 shows a more detailed circuit diagram of the first electrical circuit with the omission of control electronics 22. A first voltmeter 30, designed as a differential amplifier, measures the first cell voltage U_{Z1} that drops across the first subsection. First voltage regulator 6 comprises an error amplifier, at the first input of which the actual value, output by first voltmeter 30, of the first cell voltage U_{Z1} is applied and at the second input of which the setpoint value, output by digital-to-analog converter 12, of the first cell voltage U_{Z1} is applied. The output voltage of the differential amplifier is applied in each case as a base voltage to one of two transistors, one of which is designed as an NPN transistor and one as a PNP transistor. The respective emitter-collector voltage of both transistors is applied by voltage source 4.

As soon as microcontroller 8 changes the setpoint value for U_{Z1}, a difference between the setpoint value and the actual value of U_{Z1} occurs, which causes the error amplifier to adjust the base voltage applied to the NPN transistor and the base voltage applied to the PNP transistor. The error amplifier is set up to increase the base voltage if the setpoint value of U_{Z1} is higher than the actual value and to reduce the base voltage if the setpoint value of U_{Z1} is lower than the actual value. Depending on whether microprocessor 8 increases or reduces the setpoint value for U_{Z1}, either the resistance of the NPN transistor increases and the resistance of the PNP transistor decreases, or vice versa.

Because only one of the two transistors, either the NPN transistor or the PNP transistor, is always connected conductively, there is an electrical separation of the simulated charging current and the simulated discharging current, so that both can be measured independently of each other. The current path leading across the NPN transistor represents the discharging current of the first battery cell, and the current path leading across the PNP transistor represents the charging current of the first battery cell.

The control circuit for the second cell voltage U_{Z2} with second voltage regulator 7 and a second voltmeter 32 has an analogous structure, wherein, however, due to the reversed polarity of the second cell voltage U_{Z2} compared to the first cell voltage U_{Z1}, the NPN transistor and the PNP transistor are functionally reversed. The current path leading across the NPN transistor represents the charging current of the second battery cell, and the current path leading across the PNP transistor represents the discharging current of the second battery cell.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A battery simulator comprising:
a first electrical circuit having a first cell voltage, dropping across a first subsection of the first electrical circuit, for simulating the electrical voltage of a first battery cell;
a controller to regulate the first cell voltage, the first cell voltage being connected to a local circuit ground; and
a second cell voltage regulated by the controller and dropping across a second subsection of the first electrical circuit, the second cell voltage being connected to the same local circuit ground to simulate an electrical voltage of a second battery cell,
wherein the second cell voltage is connected in series to the first cell voltage such that the local circuit ground forms a pole of the first cell voltage and the second cell voltage.

2. The battery simulator according to claim 1, wherein the first electrical circuit comprises:
a voltage source arranged to apply a supply voltage to the first electrical circuit for operating the electrical components of the first electrical circuit;
a first voltage regulator, which is supplied by the supply voltage and which is arranged to apply the first cell voltage to the first subsection and to regulate it to a first setpoint value;
an inverse converter, which is supplied by the supply voltage and which is connected in parallel to the first voltage regulator; and
a second voltage regulator, which is supplied by the output voltage of the inverse converter and which is arranged and designed to apply the second cell voltage to the second subsection and to regulate it to a second setpoint value,
wherein the controller is set up to specify the first setpoint value to the first voltage regulator such that the first setpoint value is the same as a target specification for the electrical voltage of the first battery cell and to specify the second setpoint value to the second voltage regulator such that the second setpoint value is the same as the negative value of a target specification for the electrical voltage of the second battery cell.

3. The battery simulator according to claim 1, further comprising a second electrical circuit, which is designed substantially identical to the first electrical circuit, to provide a third cell voltage for simulating the electrical voltage of a third battery cell and a fourth cell voltage for simulating the electrical voltage of a fourth battery cell, the second electrical circuit being electrically connected to the first electrical circuit such that the first cell voltage, the second cell voltage, the third cell voltage, and the fourth cell voltage are connected in series.

4. The battery simulator according to claim 1, wherein the controller comprises control electronics, the control electronics comprising:
a digital isolator;
a microcontroller;
a digital-to-analog converter;
an analog-to-digital converter;
a differential amplifier, and
an auxiliary voltage supply to provide an operating voltage for the control electronics.
